(19) United States
(12) Patent Application Publication
(10) Pub. No.: US 2010/0239747 A1
(43) Pub. Date: Sep. 23, 2010

(54) SHADOW MASK AND EVAPORATION SYSTEM INCORPORATING THE SAME

(75) Inventors: Hsien-Hsin YEH, Sanchong City (TW); Yao-An Mo, Tainan City (TW)

Correspondence Address: RABIN & Berdo, PC, 1101 14TH STREET, NW, SUITE 500, WASHINGTON, DC, 20005, US

(73) Assignee: AU OPTRONICS CORP., Hsin-Chu (TW)

(21) Appl. No.: 12/792,199

(22) Filed: Jun. 2, 2010

Related U.S. Application Data
(62) Division of application No. 11/527,422, filed on Sep. 27, 2006.

(30) Foreign Application Priority Data
May 18, 2006 (TW) 95117718

(51) Int. Cl. B05D 5/12; C23C 16/00

(52) U.S. Cl. 427/66; 118/721

(57) ABSTRACT

A shadow mask and an evaporation system incorporating the same. The shadow mask comprises at least one opening. The length and the width of the opening range from about 100 μm to about 2000 μm and from about 25 μm to about 75 μm, respectively.

This application is a Divisional Application of co-pending U.S. application Ser. No. 11/527,422 filed Sep. 27, 2006, the subject matter of which is incorporated herein by reference.

### BACKGROUND OF THE INVENTION

1. Field of the Invention

The invention relates in general to a shadow mask and an evaporation system incorporating the same, and more particularly, to a shadow mask capable of alleviating the particles adhered to the edge of the opening of the shadow mask from scratching or pressing the substrate and an evaporation system incorporating the same.

2. Description of the Related Art

Unlike an ordinary liquid crystal display (LCD) panel which illuminates through a backlight source, an OLED panel is current driven or voltage driven to illuminate. Therefore, the OLED panel is featured by self-luminance, full-color, and wide view-angle. The OLED panel may be further applied to portable electronic devices such as mobile phone and personal digital assistant (PDA) and has gained great potential.

A conventional OLED panel includes an upper cover and a thin film transistor (TFT) substrate. The upper cover is parallel to and coupled to the TFT substrate through a sealant. The TFT substrate includes a number of red pixels, blue pixels and green pixels and a number of organic electroluminescent devices (OELD). The OELDs are disposed in the red pixels, the green pixels and the blue pixels. Each OELD includes an anode, a cathode and an emissive material layer. The emissive material layer is disposed between the anode and the cathode.

During the conventional evaporation process of OLED, the part of the pixels not covered by the emissive material layer are covered by a metallic shadow mask while the part of the pixels covered by the emissive material layer are exposed. One opening corresponds to one exposed pixel.

### SUMMARY OF THE INVENTION

It is therefore an object of the invention to provide a shadow mask and an evaporation system incorporating the same. One opening of the shadow mask corresponds to at least two pixels on the substrate. When an evaporation process is applied to the substrate of the OLED panel through the shadow mask by the evaporation system, the impact on the substrate is largely lessened when the substrate is scratched or pressed by the particles adhered onto the edge of the opening of the shadow mask or when the metallic shadow mask has a bumpy surface. Consequently, the occurrences of dark spots, which arise when the OELD of the pixel is scratched or pressed, are reduced.

The invention achieves the first object by providing a shadow mask including at least one opening. The length of the opening ranges from about 100 μm to about 2000 μm. The width of the opening ranges from about 25 μm to about 75 μm.

The invention further achieves the second object by providing an evaporation system including a chamber, a heater, a retainer and a shadow mask. The heater is disposed in the chamber for heating an evaporation source. The retainer is disposed in the chamber for retaining a to-be-evaporated body. The shadow mask disposed between the heater and the retainer includes at least one opening. The length of the opening ranges from about 100 μm to about 2000 μm. The width of the opening ranges from about 25 μm to about 75 μm.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a top view illustrating the alignment between the shadow mask and the substrate according to a first embodiment of the invention;

FIG. 2 is a top view illustrating the alignment between the shadow mask and the substrate according to a second embodiment of the invention;

FIG. 3 is a top view illustrating the alignment between the shadow mask and the substrate according to a third embodiment of the invention;

FIG. 4 is a top view illustrating the alignment between the shadow mask and the substrate according to a fourth embodiment of the invention;

FIG. 5 is a top view illustrating the alignment between the shadow mask and the substrate according to a fifth embodiment of the invention;

FIG. 6 is a top view illustrating the alignment between the shadow mask and the substrate according to a sixth embodiment of the invention;

FIG. 7 is a side view of the evaporation system according to a seventh embodiment of the invention;

FIG. 8 is a flowchart of a method for manufacturing the OLED panel according to an eighth embodiment of the invention;

FIG. 9 is a flowchart of the manufacturing process corresponding to step 84 of FIG. 8;

FIGS. 10A˜10C respectively illustrate the side views of the manufacturing process corresponding to step 91, step 93 and step 95 of FIG. 9; and

FIGS. 11A˜11B respectively illustrate the top views of the manufacturing process corresponding to step 92 and step 94 of FIG. 9.

### DETAILED DESCRIPTION OF THE INVENTION

### First Embodiment

During the conventional evaporation process of OLED, however, particles may be adhered onto the edge of the opening of the shadow mask during the evaporation process of the emissive material layer, and an uneven surface to the metallic shadow mask may occur. If the evaporation process continues to be applied to the substrate disposed on the metallic shadow mask, the metallic shadow mask may scratch or press the substrate. To the worse, the anode and cathode of the OELD of the pixels may be mistakenly activated and cause dark spots to the pixel.

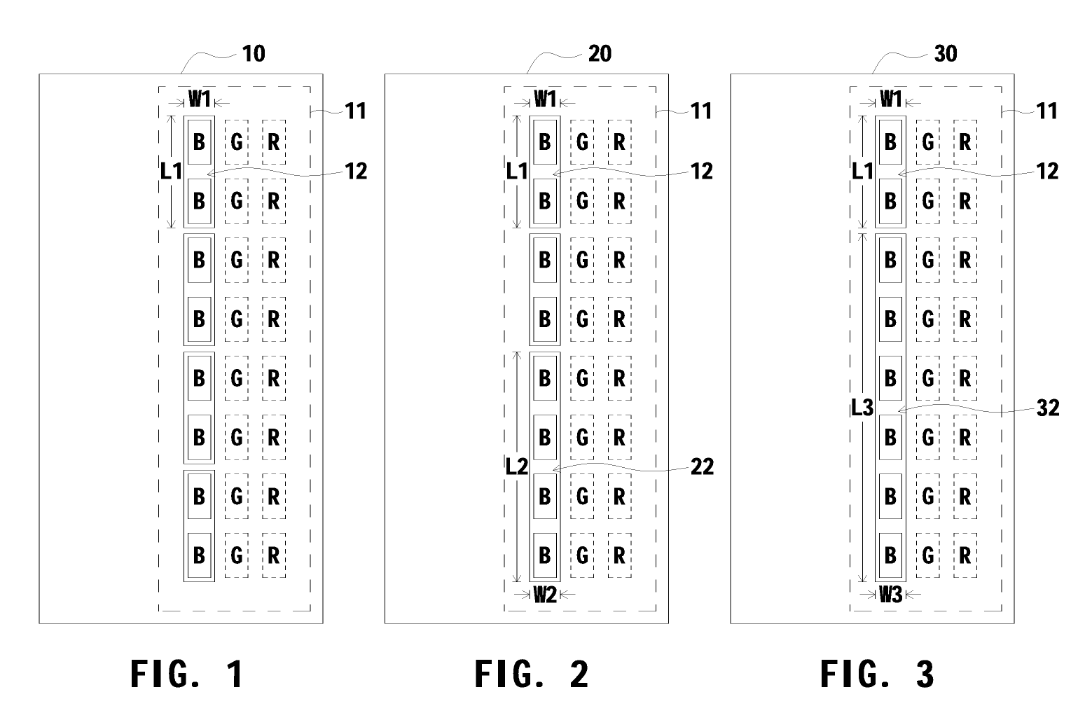

Referring to FIG. 1, a top view illustrating the alignment between the shadow mask and the substrate according to a first embodiment of the invention is shown. As shown in FIG. 1, the shadow mask 10 includes at least an opening 12 and is exemplified by having four openings 12 in the present embodiment of the invention. The length L1 of each opening 12 ranges from about 100 μm to about 2000 μm and is exemplified by being 200 μm in the present embodiment of the invention. The width W1 ranges from about 25 μm to about 75 μm and is exemplified by being 25 μm in the present embodiment of the invention. The openings 12 may be arranged in a straight line at an equal distance or unequal distances from top to down to form an opening group. The shape of the opening 12 may be a square, a quasi-square or an ellipse. However, the number and the shape of the opening 12 are not limited to the above disclosure and may be adjusted to fit actual needs. Furthermore, the size of each opening 12 may be the same or different. Besides, examples of the shadow mask 10 include a magnetic metallic shadow mask made from nickel-iron alloy or a non-magnetic metallic shadow mask made from stainless steel. The shadow mask 10 may be integrally formed into one piece.

The shadow mask 10 is disposed in correspondence to the substrate 11 for the substrate 11 to form an evaporation layer during an evaporation process. Examples of the evaporation layer are emissive material layers of different colors in the OLED panel. The substrate 11 has a pixel array. The pixel array has several columns of pixel groups, such as one column of red pixel group, one column of green pixel group and one column of blue pixel group. The column of red pixel group has eight red pixels R arranged at a constant distance from top to down. The column of green pixel group has eight green pixels G arranged at a constant distance from top to down. The column of blue pixel group has eight blue pixels B arranged at a constant distance from top to down. The openings 12 of the shadow mask 10 correspond to the pixel groups of the same color, and each opening 12 corresponds to at least two but at most twenty pixels of the same color. Each opening 12 of the shadow mask 10 corresponds to two vertically adjacent pixels of the same color of the pixel group in the same column. In the present embodiment of the invention, each opening 12 corresponds to two vertically adjacent blue pixels B of the blue pixel group in the same column such that an evaporation process is applied to form a blue emissive material layer on the blue pixels B. Then, through relative movement between the shadow mask 10 and the substrate 11, that is, the shadow mask 10 is fixed while the substrate 11 is shifted leftwards or the substrate 11 is fixed while the shadow mask 10 is shifted rightwards, each opening 12 corresponds to two vertically adjacent green pixels G of the pixel group in the same column such that an evaporation process is applied to form a green emissive material layer on the green pixels G. Afterward, through relative movement between the shadow mask 10 and the substrate 11, each opening 12 corresponds to two vertically adjacent red pixels R of the pixel group in the same column such that an evaporation process is applied to form a red emissive material layer on the red pixels R.

Any one who is skilled in the technology of the present embodiment of the invention will understand that the technology of the present embodiment of the invention is not limited thereto. For example, the size of each opening 12 is at least larger than the area of two pixels of the same color. Furthermore, the red pixels R, the green pixels G and the blue pixels B respectively have an electrode, such that the red emissive material layer, the green emissive material layer and the blue emissive material layer are correspondingly formed on the electrodes of the red pixels R, the green pixels G and the blue pixels B. Apart from the design of having the opening 12 corresponding to at least two pixels, the opening of the shadow mask 10 may correspond to one pixel only. The design of the opening of the shadow mask 10 is adjusted to fit actual needs.

In the present embodiment of the invention, the opening 12 of the shadow mask 10 corresponds to at least two pixels on the substrate 11, thus reducing the number of the openings 12 of the shadow mask 10. Consequently, when the evaporation process is applied to the substrate 11 of the OLED panel through the shadow mask 10, the openings 12 have fewer edges, largely lessening the impact on the substrate when the particles adhered onto the edges of the openings 12 of the shadow mask 10 scratch or press the substrate 11.

### Second Embodiment

Referring to FIG. 2, a top view illustrating the alignment between the shadow mask and the substrate according to a second embodiment of the invention is shown. The shadow mask 20 of the present embodiment of the invention differs from the shadow mask 10 of the first embodiment in the design of the opening. As shown in FIG. 2, the shadow mask 20 includes at least one opening and is exemplified by having two openings 12 and an opening 22. The length L2 of the opening 22 and the length L1 of each opening 12 both range from about 100 μm to about 2000 μm. The width W2 of the opening 22 and the width W1 of each opening 12 both range from about 25 μm to about 75 μm. The size of the opening 22 is larger than the size of the opening 12. For example, the length L2 of the opening 22 is larger than the length L1 of each opening 12. In the present embodiment of the invention, the length L2 of the opening 22 is 400 μm. In the present embodiment of the invention, the width W2 of the opening 22 is 25 μm and is equal to the width W1 of each opening 12. In the present embodiment of the invention, the openings 12 and 22 are arranged in a straight line at a constant distance from top to down to form an opening group. The shape of the openings 12 and 22 respectively are a square, a quasi-square or an ellipse. Furthermore, examples of the shadow mask 20 include a magnetic metallic shadow mask made from nickel-iron alloy or a non-magnetic metallic shadow mask made from stainless steel. The shadow mask 20 may be integrally formed into one piece.

The shadow mask 20 corresponds to the substrate 11 for emissive material layers of different colors formed on the substrate 11 during an evaporation process. In the present embodiment of the invention, each opening 12 corresponds to two adjacent blue pixels B while the opening 22 corresponds to four adjacent blue pixels B, such that the evaporation process of forming a blue emissive material layer is applied. Then, through relative movement between the shadow mask 20 and the substrate 11, the evaporation process of forming a green emissive material layer on the green pixels G and the evaporation process of forming a red emissive material layer on the red pixels R are sequentially applied. Any one who is skilled in the technology of the present embodiment of the invention will understand that the technology of the present embodiment of the invention is not limited thereto. For example, the size of the opening 22 is at least larger than the area of four pixels of the same color.

### Third Embodiment

Referring to FIG. 3, a top view illustrating the alignment between the shadow mask and the substrate according to a third embodiment of the invention is shown. The shadow mask 30 of the present embodiment of the invention differs from the shadow mask 10 of the first embodiment in the design of the opening. As shown in FIG. 3, the shadow mask 30 includes at least one opening and is exemplified by an opening 12 and an opening 32. The length L3 of the opening 32 and the length L1 of the opening 12 both range from about 100 μm to about 2000 μm. The width W3 of the opening 32 and the width W1 of the opening 12 both range from about 25 μm to about 75 μm. The size of the opening 32 is larger than the size of the opening 12. For example, the length L3 of the opening 32 is larger than the length L1 of the opening 12. In the present embodiment of the invention, the length L3 of the opening 32 is 600 μm. In the present embodiment of the invention, the width W3 of the opening 32 is 25 μm and is equal to the width W1 of the opening 12. In the present embodiment of the invention, the openings 12 and 32 are arranged in a straight line at a constant distance from top to down to form an opening group. The shapes of the openings 12 and 32 are a square, a quasi-square or an ellipse. Furthermore, examples of the shadow mask 30 include a magnetic metallic shadow mask made from nickel-iron alloy or a non-magnetic metallic shadow mask made from stainless steel. The shadow mask 30 may be integrally formed into one piece.

The shadow mask 30 corresponds to the substrate 11 for emissive material layers of different colors formed on the substrate 11 during an evaporation process. In the present embodiment of the invention, the opening 12 corresponds to two adjacent blue pixels B, the opening 32 corresponds to six adjacent blue pixels B, such that the evaporation process of forming a blue emissive material layer is applied. Then, through relative movement between the shadow mask 30 and the substrate 11, the evaporation process of forming a green emissive material layer on the green pixels G and the evaporation process of forming a red emissive material layer on the red pixels R are sequentially applied. Any one who is skilled in the technology of the present embodiment of the invention will understand that the technology of the present embodiment of the invention is not limited thereto. For example, the size of the opening 32 is at least larger than the area of six pixels of the same color.

### Fourth Embodiment

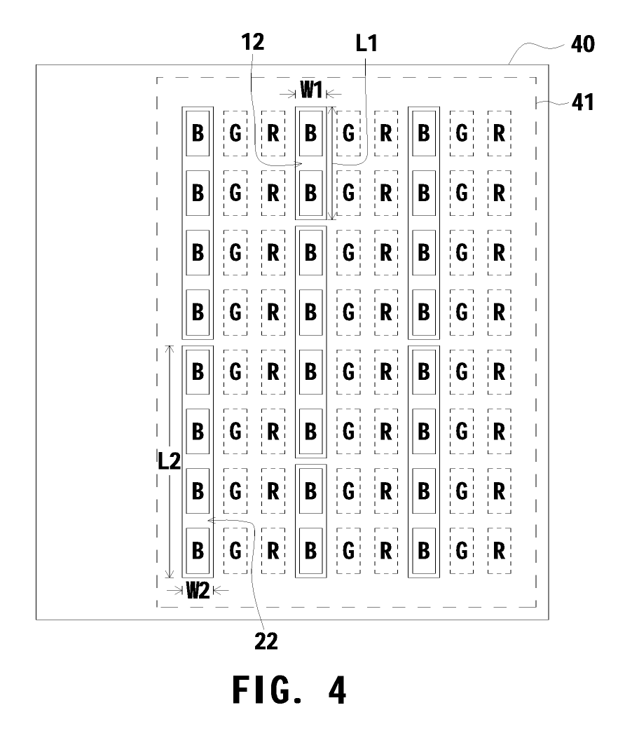

Referring to FIG. 4, a top view illustrating the alignment between the shadow mask and the substrate according to a fourth embodiment of the invention is shown. The shadow mask 40 of the present embodiment of the invention differs from the shadow mask 20 of the second embodiment in the design of the opening. As shown in FIG. 4, the shadow mask 40 includes at least one opening and is exemplified by two openings 12 and five openings 22. The ranges of the length and the width of the openings 12 and the openings 22 are disclosed in the first and the second embodiments and are not repeated here. The openings 22 of the same size are arranged in a stair-shape. For example, three openings 22 are arranged in a descending manner from the left top of the shadow mask 40 down to the right bottom of the shadow mask 40 like a stair. Alternatively, the three openings 22 are arranged in an ascending manner from the left bottom of the shadow mask 40 up to the right top of the shadow mask 40 like a stair. The stair design of the openings 22 of the present embodiment of the invention enhances the structural strength of the shadow mask 40, and will not be bent or deformed easily. Furthermore, examples of the shadow mask 40 include a magnetic metallic shadow mask made from nickel-iron alloy or a non-magnetic metallic shadow mask made from stainless steel. The shadow mask 40 may be integrally formed into one piece.

The shadow mask 40 corresponds to the substrate 41 for emissive material layers of different colors formed on the substrate 41 during an evaporation process. The substrate 41 has a pixel array. The pixel array has several columns of pixel groups. For example, the pixel array has three columns of red pixel group, three columns of green pixel group and three columns of blue pixel group. Each column of red pixel group has eight red pixels R arranged in a constant distance from top down. Each column of green pixel group has eight green pixels G arranged in a constant distance from top to down. Each column of blue pixel group has eight blue pixels B arranged in a constant distance from top to down. The openings 12 and 22 of the shadow mask 40 correspond to all pixels having the same color. Each opening 12 corresponds to two vertically adjacent blue pixels B of the blue pixel group in the same column, and each opening 22 corresponds to four vertically adjacent blue pixels B of the blue pixel group in the same column, such that the evaporation process of forming a blue emissive material layer on the blue pixels B is applied. Then, through relative movement between the shadow mask 40 and the substrate 41, the evaporation process of forming a green emissive material layer and the evaporation process of forming a red emissive material layer are sequentially applied.

### Fifth Embodiment

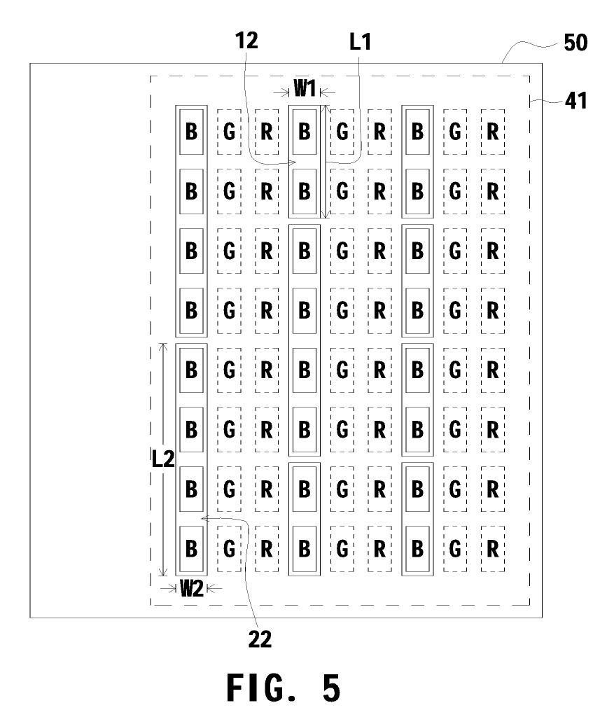

Referring to FIG. 5, a top view illustrating the alignment between the shadow mask and the substrate according to a fifth embodiment of the invention is shown. The shadow mask 50 of the present embodiment of the invention differs from the shadow mask 40 of the fourth embodiment in the design of the opening. As shown in FIG. 5, the shadow mask 50 includes at least one opening and is exemplified by five openings 12 and two openings 22. The ranges of the length and width of the openings 12 and the opening 22 are disclosed in the first and the second embodiments and are not repeated here. The openings 12 and 22 have different sizes and are arranged in a stair-shape. For example, two openings 22 and an opening 12 are arranged in a descending manner from the left top of the shadow mask 50 down to the right bottom of the shadow mask 50 like a stair. Alternatively, the two openings 22 and the opening 12 are arranged in an ascending manner from the left bottom of the shadow mask 50 up to the right top of the shadow mask 50 like a stair. Furthermore, examples of the shadow mask 50 include a magnetic metallic shadow mask made from nickel-iron alloy or a non-magnetic metallic shadow mask made from stainless steel. The shadow mask 50 may be integrally formed into one piece.

The shadow mask 50 corresponds to the substrate 41 for emissive material layers of different colors to be formed on the substrate 41 during an evaporation process. The openings 12 and 22 of the shadow mask 50 correspond to all pixels having the same color. Each opening 12 corresponds to two vertically adjacent blue pixels B of the blue pixel group in the same column, each opening 22 corresponds to four vertically adjacent blue pixels B of the blue pixel group in the same column, such that the evaporation process of forming a blue emissive material layer on the blue pixels B is applied. Then, through relative movement between the shadow mask 50 and the substrate 41, the evaporation process of forming a green emissive material layer on the green pixel G and the evaporation process of forming a red emissive material layer on the red pixels R are respectively applied.

### Sixth Embodiment

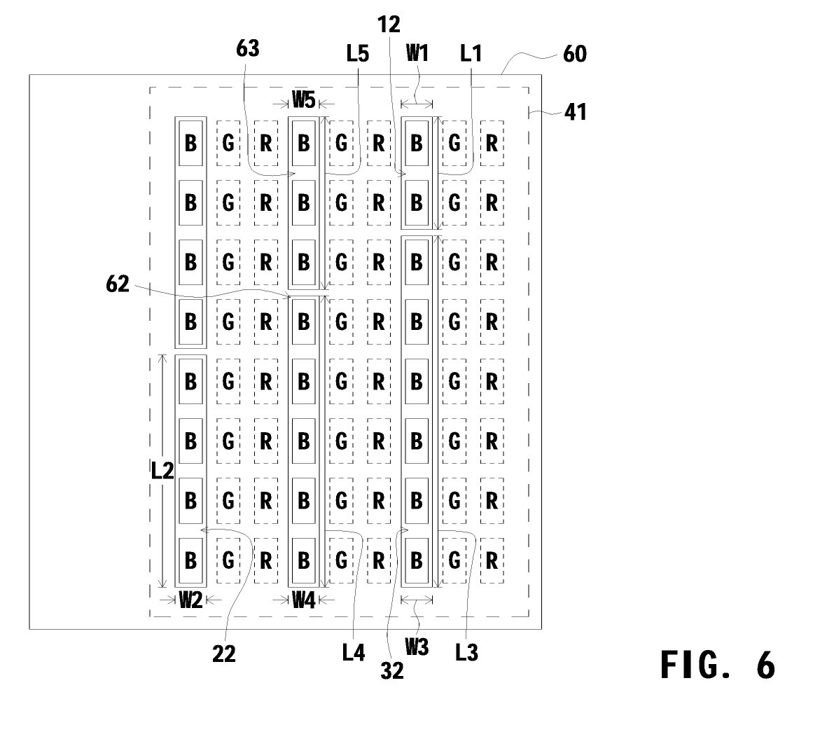

Referring to FIG. 6, a top view illustrating the alignment between the shadow mask and the substrate according to a sixth embodiment of the invention is shown. The shadow mask 60 of the present embodiment of the invention differs from the shadow mask 40 of the fourth embodiment in the design of the opening. As shown in FIG. 5, the shadow mask 60 includes at least one opening and is exemplified by an opening 12, two openings 22, an opening 32, an opening 62 and an opening 63. The length L4 of the opening 62 and the length L5 of the opening 63 range from about 100 μm to about 2000 μm. The width W4 of the opening 62 and the width W5 of the opening 63 range from about 25 μm to about 75 μm. The ranges of the length and the width of the opening 12, 22 and 32 are disclosed in the first, the second and the third embodiments, and are not repeated here. The size of the opening 32 is larger than that of the opening 62. The size of the opening 62 is larger than that of each opening 22. In the present embodiment of the invention, the length L4 of the opening 62 is 500 μm, the length L5 of the opening 63 is 300 μm, and both the width W4 of the opening 62 and the width W5 of the opening 63 are 25 μm. The size of each opening 22 is larger than that of the opening 63, and the size of the opening 63 is larger than that of the opening 12. The openings 22, 62 and 32 have different sizes and are arranged in a stair-shape. For example, the openings 22, 62 and 32 are arranged in an ascending manner from the left bottom of the shadow mask 60 up to the right top of the shadow mask 60. Furthermore, examples of the shadow mask 60 include a magnetic metallic shadow mask made from nickel-iron alloy or a non-magnetic metallic shadow mask made from stainless steel. The shadow mask 60 may be integrally formed into one piece.

The shadow mask 60 corresponds to the substrate 41 for emissive material layers of different colors formed on the substrate 41 during an evaporation process. The openings 12, 22, 32, 62 and 63 of the shadow mask 60 correspond to all pixels having the same color. The opening 12 corresponds to two vertically adjacent blue pixels B of the blue pixel group in the same column. Each opening 22 corresponds to four vertically adjacent blue pixels B of the blue pixel group in the same column. The opening 63 corresponds to three vertically adjacent blue pixels B of the blue pixel group in the same column. The opening 62 corresponds to five vertically adjacent blue pixels B of the blue pixel group in the same column. Thus, the evaporation process of forming a blue emissive material layer on the blue pixels B is applied. Then, through relative movement between the shadow mask 60 and the substrate 41, the evaporation process of forming a green emissive material layer on the green pixels G and the evaporation process of forming a red emissive material layer on the red pixels R are sequentially applied. Any one who is skilled in the technology of the present embodiment of the invention will understand that the technology of the present embodiment of the invention is not limited thereto. For example, the size of the opening 62 is at least larger than the area of five pixels having the same color and the size of the opening 63 is at least larger than the size of three pixels having the same color.

### Seventh Embodiment

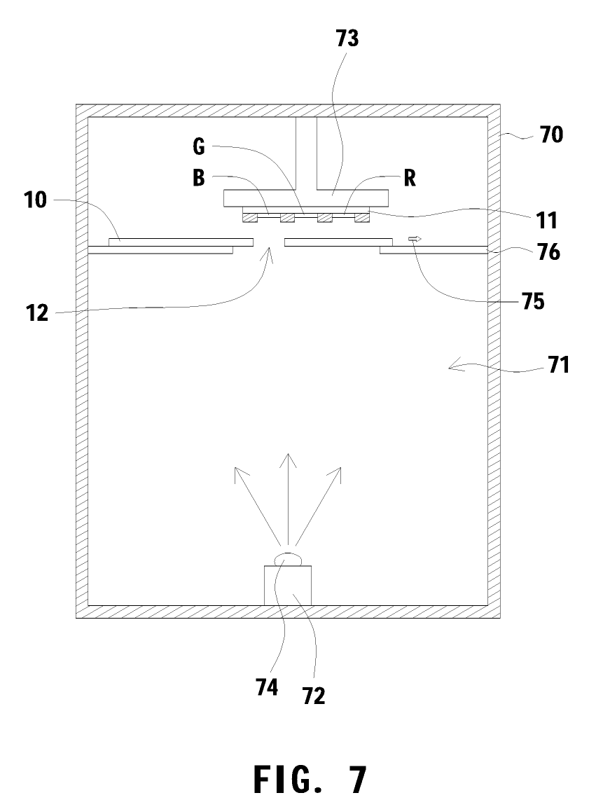

Referring to FIG. 7, a side view of the evaporation system according to a seventh embodiment of the invention is shown. As shown in FIG. 7, the evaporation system 70 includes a chamber 71, a heater 72, a retainer 73 and one of the shadow masks disclosed in the above embodiments. The shadow mask is exemplified by the shadow mask 10 of the first embodiment. The heater 72 is disposed in the chamber 71 for carrying and heating an evaporation source 74, such that the evaporation source 74 is evaporated. The retainer 73 is disposed in the chamber 71 for retaining a to-be-evaporated body. In the present embodiment of the invention, the evaporation source 74 includes at least an organic light emitting material. The formation of emissive material layers of different colors on the substrate requires organic emissive material layers of different colors. The to-be-evaporated body is exemplified by the substrate 11 of the OLED panel. The shadow mask 10 including at least an opening 12 is disposed between the heater 72 and the retainer 73. The length L1 of the opening 12 ranges from about 100 μm to about 2000 μm, and the width W1 of the opening 12 ranges from about 25 μm to about 75 μm. In the present embodiment of the invention, the evaporation system 70 further includes a carrying element 76 disposed between the heater 72 and the retainer 73 for carrying the shadow mask 10 such that the shadow mask 10 is firmly shifted along the direction of the arrow 76. Furthermore, on the substrate 11, each one of the red pixels R, the green pixels G and the blue pixels B has an electrode. After the steps of changing the evaporation source 74 of organic light emitting materials of different colors, heating and evaporating the evaporation source 74 and shifting the shadow mask 10 along the direction of the arrow 75, the evaporated blue, green and red organic light emitting materials sequentially form a blue emissive material layer, a green emissive material layer and a red emissive material layer on the electrodes of the blue pixels B, the green pixels G and the red pixels R via the opening 12.

Any one who is skilled in the technology of the present embodiment of the invention will understand that the technology of the present embodiment of the invention is not limited thereto. For example, the heater 72 is a heating wire. After a high current flows through the tungsten filament of the heating wire, for example, the heating wire is heated and high temperature is generated for heating the evaporation source 74 into a fluid such as a liquid or a gas first, and then the fluid is evaporated into the chamber 71. If the shadow mask 10 is a magnetic metallic shadow mask, the retainer 73 attracts and retains the shadow mask 10 by magnetism. Therefore, the shadow mask 10 is mounted over the substrate 11 even tightly, such that the gap between the shadow mask 10 and the substrate 11 is substantially avoided, and the organic light emitting material is prevented from being evaporated into an incorrect position on the substrate 11. An organic light emitting material may be evaporated into an incorrect position on the substrate 11, such as the blue organic light emitting material may be evaporated into the adjacent green pixel G when clearance exists between the shadow mask 10 and the substrate 11.

When the evaporation system 70 applies evaporation process to the substrate 11 of the OLED panel via the shadow mask 10, the design that the opening 12 of the shadow mask 10 corresponds to the substrate at least two pixels largely lessens the impact on the substrate when the particles adhered onto the edges of the openings 12 of the shadow mask 10 scratch or press the substrate 11.

### Eighth Embodiment

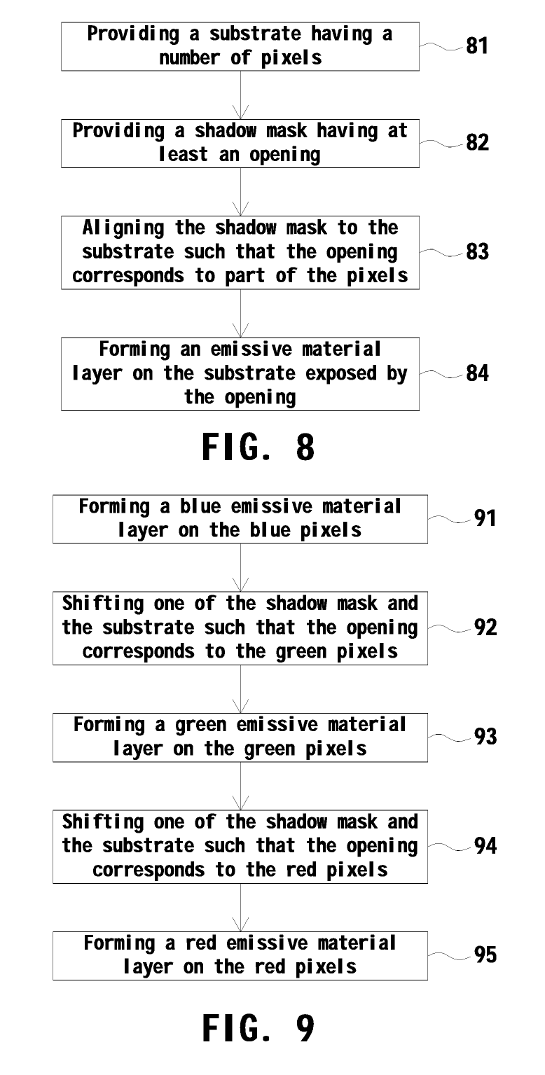

Referring to FIG. 8, a flowchart of a method for manufacturing the OLED panel according to an eighth embodiment of the invention is shown. Firstly, in step 81, a substrate having several pixels is provided. Then, proceeding to step 82, a shadow mask having at least one opening is provided. The length of the opening ranges from about 100 μm to about 2000 μm. The width of the opening ranges from about 25 μm to about 75 μm. Afterward, proceeding to step 83, the shadow mask is aligned to the substrate, such that the opening corresponds to part of the pixels. In the present embodiment of the invention, the shadow mask and the substrate disclosed in steps 81˜83 are the shadow mask and the substrate disclosed in the first to the fifth embodiments and are exemplified by the shadow mask 10 and the substrate 11 here. In FIG. 1, the pixels of the substrate 11 include a number of red pixels R, green pixels G and blue pixels B and are exemplified by eight red pixels R, eight green pixels G and eight blue pixels B, respectively. Each of the red pixels R, the green pixels G and the blue pixels B has an electrode. Examples of the substrate 11 include a thin film transistor (TFT) substrate. The shadow mask 10 has four openings 12. The openings 12 are arranged in a straight line. The length L1 of each opening 12 ranges from about 100 μm to about 2000 μm. The width W1 of each opening 12 ranges from about 25 μm to about 75 μm. Each opening 12 at least corresponds to two but at most twenty blue pixels B. In the present embodiment of the invention, each opening 12 corresponds to two blue pixels B. The size of each opening 12 is larger than the area of two blue pixels B. If the present embodiment of the invention is exemplified by the shadow mask 40 of the fourth embodiment, the openings 22 of the shadow mask 40 are arranged in a stair-shape. Then, proceeding to step 84, an emissive material layer is formed on part of the substrate 11 exposed by the opening 12.

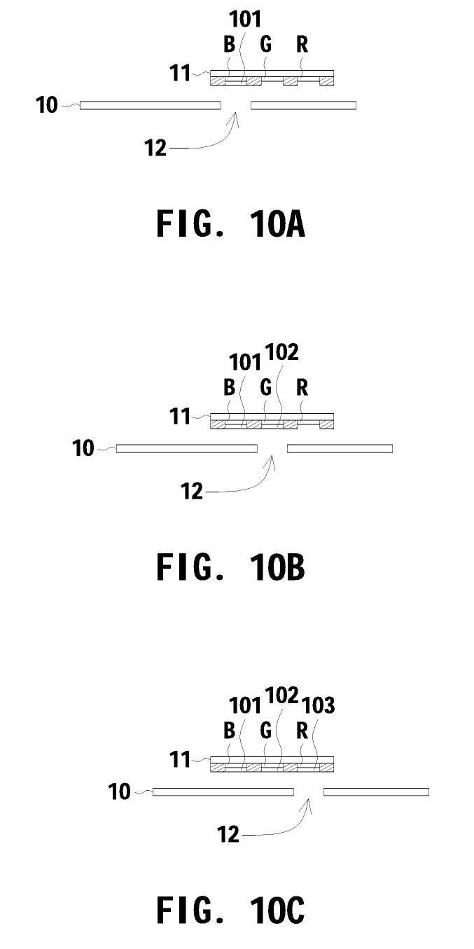

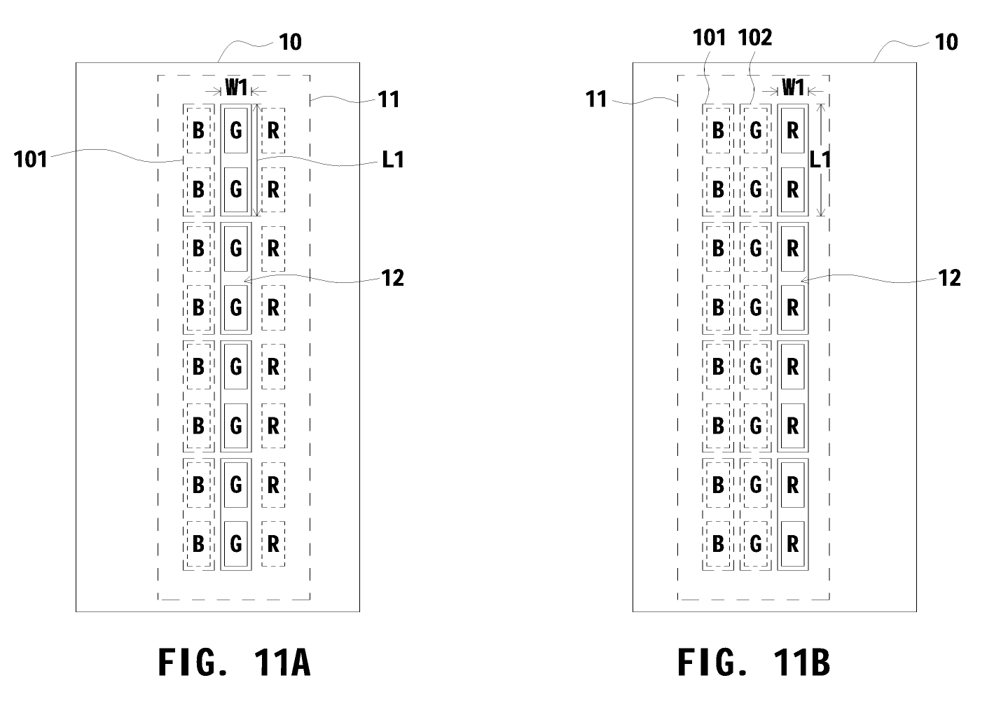

In the present embodiment of the invention, the formation of the emissive material layer on part of the substrate 11 exposed by the opening 12 is elaborated by the accompanied drawings. Referring to FIGS. 9˜11B. FIG. 9 is a flowchart of the manufacturing process corresponding to step 84 of FIG. 8. FIGS. 10A˜10C respectively illustrate the side views of the manufacturing process corresponding to step 91, step 93 and step 95 of FIG. 9. FIGS. 11A˜11B respectively illustrate the top views of the manufacturing process corresponding to step 92 and step 94 of FIG. 9.

Firstly, in step 91, as shown in FIG. 10A, a blue emissive material layer 101 is formed on part of the blue pixels B, for example, two blue pixels B. Then, proceeding to step 92, as shown in FIG. 11A, one of the shadow mask 10 and the substrate 11 is shifted. For example, the substrate is fixed while the shadow mask 10 is shifted rightwards, such that the opening 12 corresponds to part of the green pixels G, for example, two green pixels G. Afterward, proceeding to step 93, as shown in FIG. 10B, a green emissive material layer 102 is formed on part of the green pixels G, for example, two green pixels G. Then, proceeding to step 94, as shown in FIG. 11B, one of the shadow mask 10 and the substrate 11 is shifted. For example, the substrate 11 is fixed while the shadow mask 10 is shifted rightwards, such that the opening 12 corresponds to part of the red pixels R, for example, two red pixels R. Afterward, proceed to step 95, as shown in FIG. 100, a red emissive material layer 103 is formed on part of the red pixels R, for example, two red pixels R. However, the sequence of the formation of the blue emissive material layer 101, the green emissive material layer 102 and the red emissive material layer 103 is not limited to the above disclosure. It is noted that a blue emissive material layer 101, a green emissive material layer 102 and a red emissive material layer 103 are capable of respectively covering and corresponding to two blue pixels B, two green pixels G and two red pixels R. Since the emissive material layer of each color has large resistance, the luminance of the pixels is not inter-affected.

Afterwards, a continuously distributed electrode is respectively formed on the blue emissive material layer 101, the green emissive material layer 102 and the red emissive material layer 103 such that a number of organic electroluminescence devices (OELD) of the OLED panel are formed on the blue pixels B, the green pixels G and the red pixels R, respectively. One pixel may have only one OELD. The structure of the OELD is like a sandwich with one emissive material layer contained by two electrodes from atop and underneath. Any one who is skilled in the technology of the present embodiment of the invention will understand the design of other structures of the OELD such as the electron transport layer, the electron infusion layer, the hole infusion layer and the hole transport layer, and the technology of other structures of the OELD is not repeated here.

According to the shadow mask and an evaporation system incorporating the same disclosed in the above embodiments of the invention, each opening of the shadow mask corresponds to at least two pixels on the substrate such that the number of openings on the shadow mask is reduced. When the evaporation system applies an evaporation process to the substrate of the OLED panel via the shadow mask, the design that the opening of the shadow mask corresponds to the substrate at least two pixels largely lessens the impact on the substrate when the particles adhered onto the edge of opening of the shadow mask scratches or presses the substrate, hence reducing the occurrences of dark spots which arise when the OELD of the pixels is scratched or pressed.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing an organic light emitting diode (OLED) panel, comprising:
providing a substrate having a plurality of pixels;
providing a mask having at least an opening;
aligning the mask to the substrate such that the opening corresponds to part of the pixels; and
forming an emissive material layer on the substrate exposed by the opening.

2. The method according to claim 1, wherein the opening corresponds to at least two pixels but at most twenty pixels.

3. The method according to claim 1, wherein the emissive material layer is formed by evaporation.

4. The method according to claim 1, wherein the size of the opening is larger than the area of the two pixels and smaller than the area of the twenty pixels.

5. The method according to claim 1, wherein the length of the opening ranges from 100 μm to 2000 μm, and the width of the opening ranges from 25 μm to 75 μm.

6. A mask for use in the method as claim 1, wherein the mask is a shadow mask, the length of the opening ranges from 100 μm to 2000 μm, and the width of the opening ranges from 25 μm to 75 μm.
